(19) United States
(12) Patent Application Publication
(10) Pub. No.: US 2006/0255352 A1
(43) Pub. Date: Nov. 16, 2006

(54) Light emitting diode light source model

(75) Inventors: Jui-Li Lin, Taichung Hsien (TW); Yong-Yuan Xu, Xiamen City (CN)

Correspondence Address: PATENTTM.US, P. O. BOX 82788, PORTLAND, OR, 97282-0788, US

(73) Assignee: QUASAR OPTOELECTRONICS, INC.

(21) Appl. No.: 11/327,024

(22) Filed: Jan. 6, 2006

(30) Foreign Application Priority Data
May 11, 2005 (TW) 094207598
Oct. 7, 2005 (TW) 094135114

(51) Int. Cl. H01L 33/00

(52) U.S. Cl. 257/98; 257/E33.067; 257/99

(57) ABSTRACT

An LED light source model has a substrate, at least one bare LED chip, a preformed phosphor lamina with at least one inner opening, and an optical light collecting element. The substrate has a top face, a bottom face and at least one chip mounting area defined on the top face. The frame is mounted on the top face and the inner opening corresponds to the chip mounting area. The bare LED chip is mounted in the chip mounting area. The preformed phosphor lamina is mounted over the bare LED chip and mounted in the corresponding inner opening. The optical light collecting element is mounted on the top face to collect the light from each preformed phosphor lamina to increase the light intensity. Each preformed phosphor lamina is preformed to ensure that two opposite faces are flat, so the light intensity from all of the bare LED chips is even.

### BACKGROUND OF THE INVENTION

1. Field of the Invention

The present invention relates to a light emitting diode (LED) light source model, and more particularly to a light emitting diode light source model having an even light intensity, high light intensity, simple structure and high heat dissipation capabilities.

2. Description of the Related Art

The light emitting diode (LED) element is widely used as a light source for lamps or illumination devices since LED elements have low power consumption and sufficient light intensity. However, the heat generated by the LED element during operation affects the reliability of the LED element. Therefore, many companies or factories in this technology field are making efforts to find or invent some solutions to decrease the heat influence and have also devoted research to increase the light intensity of LED elements.

With reference to FIG. 9, a flat LED light source (50) having good heat dissipation capability has a substrate (51), at least one bare LED chip (52), a transparent layer (53) and an optical light collecting element (54). The substrate (50) has a top face (511), a bottom face (512) and at least one chip mounting area (521) defined on the top face (511). The at least one bare LED chip (52) is mounted in the corresponding chip mounting area (521). Liquid glue is then poured into the chip mounting area (521). When the liquid glue has solidified, the transparent layer (53) is formed on the top face (511) to seal the chip mounting area (521). The optical light collecting element (54) is further mounted on the top face (511) to collect the light from each chip mounting area (521) to increase the light intensity. In addition, a plurality of fins (514) or recesses are formed or defined on the bottom face of the substrate (51) to increase heat dissipation area. When the at least one bare LED chip (52) is operating, heat from the bare LED chip (52) will be conducted to the bottom face (512) and then dissipated to the ambient air quickly.

Although the conventional flat LED source (50) has good heat dissipation capability, light intensity is not even since the transparent layer (53) may not have a flat surface due to liquid glue solidifying to the transparent layer (53).

Therefore, the present invention provides an LED light source model that has a good and even light intensity.

### SUMMARY OF THE INVENTION

The main objective of the present invention is to provide an LED light source model suitable for flat and planar light source lamps or illumination devices that has good and even light intensity.

The LED light source model in accordance with the present invention has a substrate, at least one bare LED chip, a preformed phosphor lamina with at least one inner opening, and an optical light collecting element. The substrate has a top face, a bottom face and at least one chip mounting area defined on the top face. The frame is mounted on the top face and the inner opening corresponds to the chip mounting area. The bare LED chip is mounted in the chip mounting area. The preformed phosphor lamina is attached to the bare LED chip and mounted in the corresponding inner opening. The optical light collecting element is mounted on the top face to collect the light from each preformed phosphor lamina to increase the light intensity. Each phosphor lamina is preformed to ensure that two opposite faces are flat, so the light intensity from all of the bare LED chips is even.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a first embodiment of an LED light source model in accordance with the present invention;

FIG. 2 is a partial enlarged cross sectional view of the first embodiment of an LED light source model in FIG. 1;

FIG. 3 is an exploded perspective view of a second embodiment of an LED source model in accordance with the present invention;

FIG. 4 is a cross sectional view of a third embodiment of an LED light source model in accordance with the present invention;

FIG. 5 is an exploded perspective view of a fourth embodiment of an LED light source model in accordance with the present invention;

FIG. 6 is a cross sectional view of the fourth embodiment of the LED light source model in FIG. 5;

FIG. 7 is a perspective view of a fifth embodiment of the LED light source model in accordance with the present invention;

FIG. 8 is an exploded perspective view of a sixth embodiment of an LED light source model in accordance with the present invention; and

FIG. 9 is a cross sectional view of a conventional plan LED source in accordance with the prior art.

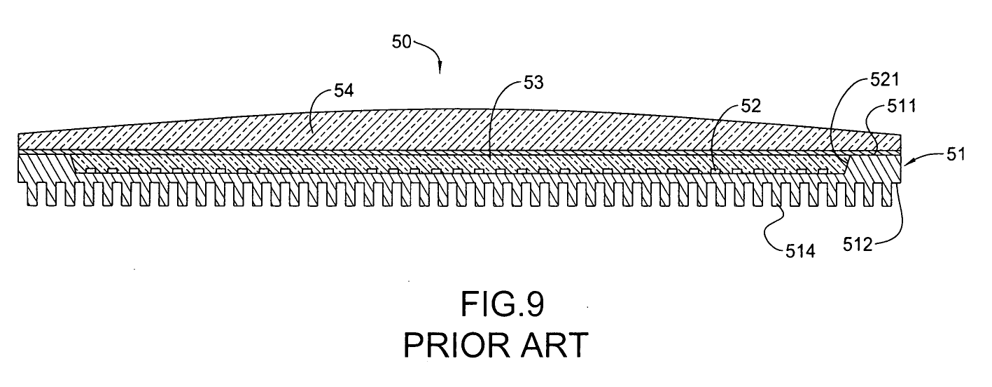

### DETAILED DESCRIPTION OF THE PREFERRED EMBODIMENT

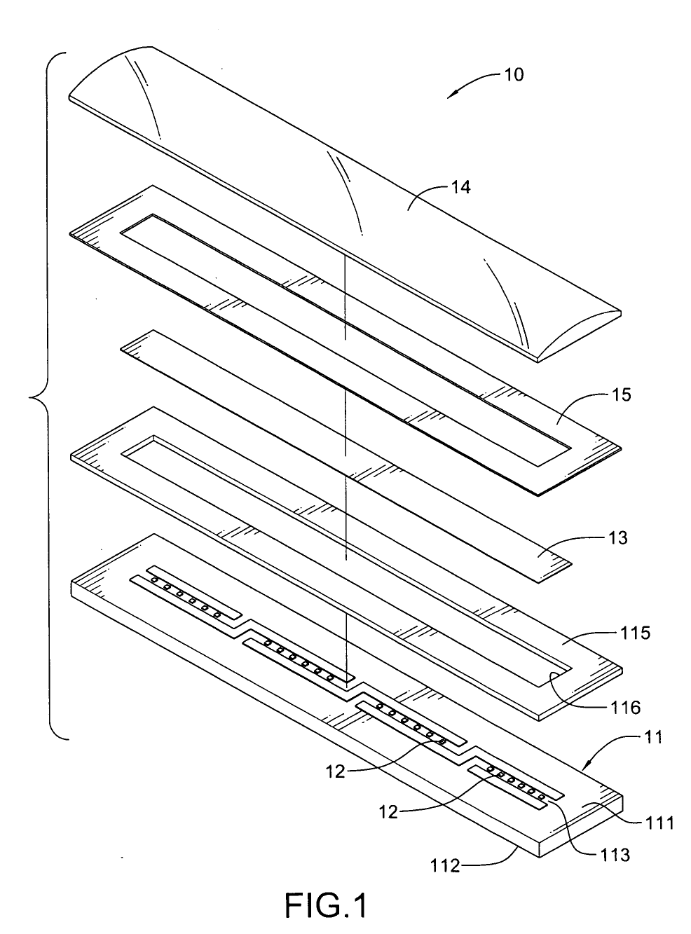

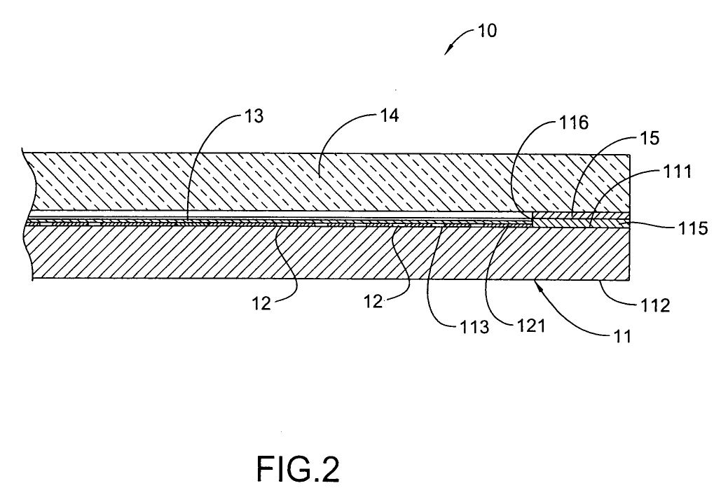

With reference to FIGS. 1 and 2, a first embodiment of an LED light source model (10) in accordance with the present invention has a substrate (11) with high thermal conductivity, at least one bare LED chip (12), an optional glue layer (121), a frame (115), at least one preformed phosphor lamina (13), an adhesive layer (15) and an optical light collecting element (14).

Since the substrate (11) has high thermal conductivity, the substrate (11) can be made of a metallic material (such as aluminum, copper, alloy or the like) or nonmetallic material (such as ceramics or the like). The substrate (11) has a top face (111), a bottom face (112), and at least one chip mounting area (113) defined on the top face (111).

The frame (115) has at least one inner opening (116) and is mounted on the top face (111) of the substrate (11). The inner opening (116) corresponds to the chip mounting area (113). The bare LED chips (12) are mounted in the chip mounting area (113). The glue layer (121) is formed in the at least one inner opening (116) to fill in between the bare LED chips (12).

The preformed phosphor lamina (13) having two opposite flat faces is mounted over the bare LED chips (12) and the glue (121), and fixed in the corresponding inner opening (116) of the frame (115).

The optical light collecting element (14) is mounted on the frame (115) to collect light through the preformed phosphor lamina (13) to increase the light intensity. The optical light collecting element (14) can be an optical lens. The optical light collecting element (14) is mounted to the frame (115) through the adhesive layer (15) or by mechanical fasteners, such as screws.

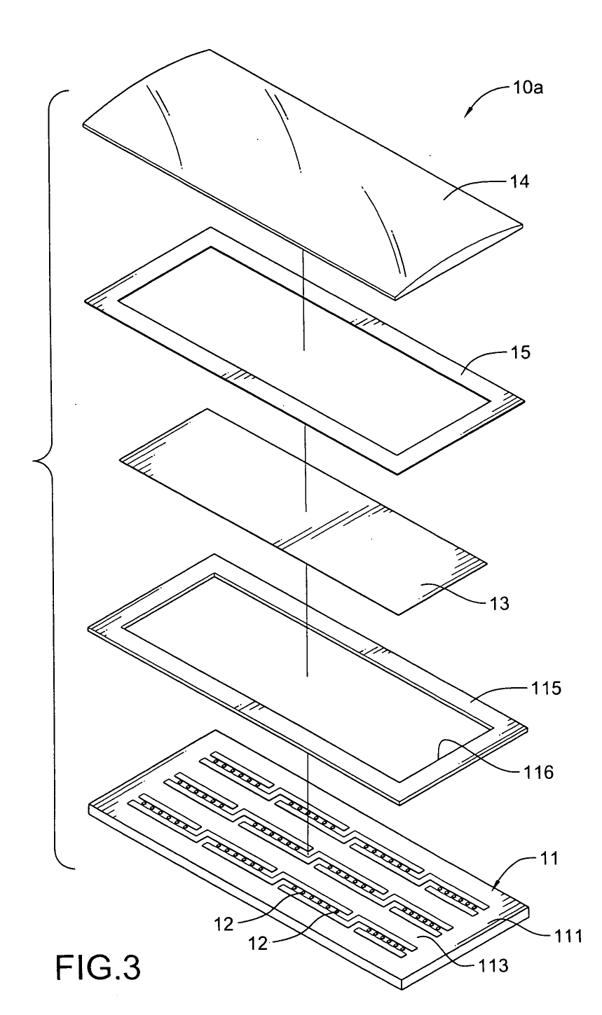

With reference to FIG. 3, a second embodiment of an LED light source model (10a) in accordance with the present invention has the same elements of the first embodiment and further uses more bare LED chips (12). A plurality of bare LED chips (12) in the chip mounting area (13) are arranged in a plurality of lines.

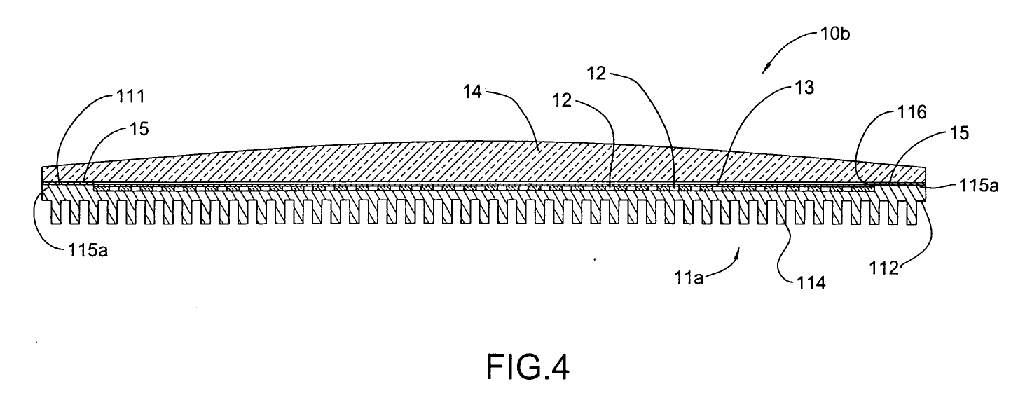

With reference to FIG. 4, a third embodiment of an LED light source model (10b) in accordance with the present invention is similar to the first embodiment. A substrate (11a) and a frame (115a) are formed integrally. Further, the substrate (11a) has a plurality of fins (114) or a plurality of recesses defined on a bottom face (112) to increase the heat dissipation area of the substrate (11). The fins (114) are formed as straight shapes and arranged parallel to each other on the bottom face (112). Therefore, the substrate (11) is also a heat sink.

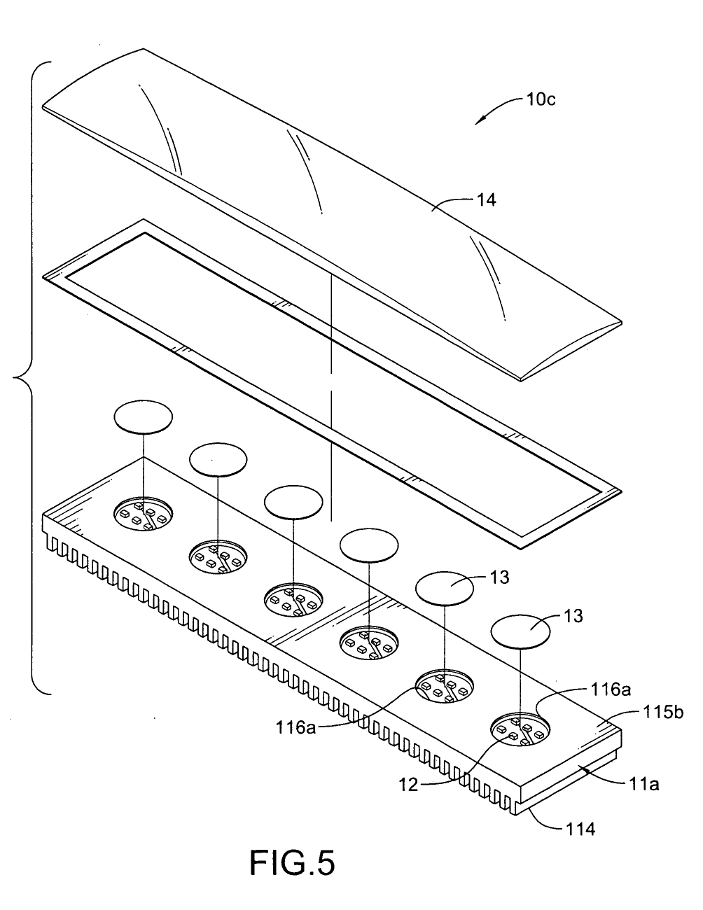

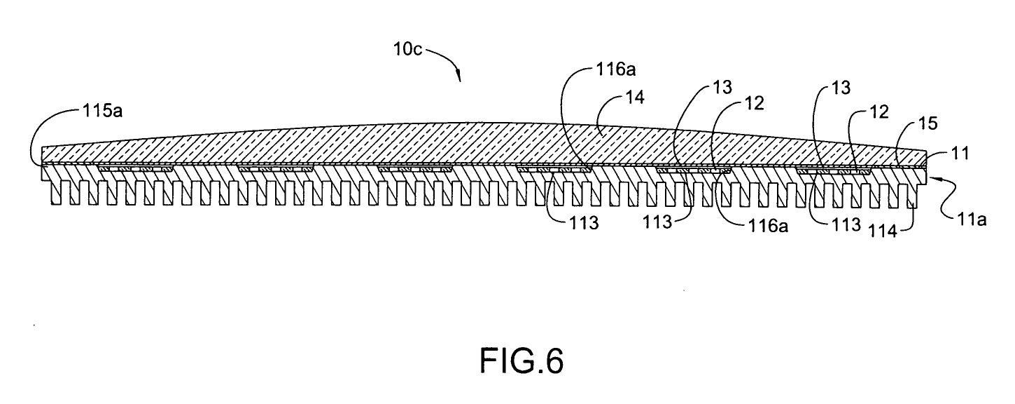

With reference to FIGS. 5 and 6, a fourth embodiment of an LED light source model (10c) in accordance with the present invention is similar to the third embodiment and has a different frame (115b), a plurality of circular preformed phosphor lamina (13) and a plurality of chip mounting areas (113) defined on the top face (111) of the substrate (11). The frame (115b) has a plurality of circular inner opening (116a) and is formed integrally with the substrate (11a). Each preformed phosphor lamina (13) is mounted in a corresponding inner opening (116a).

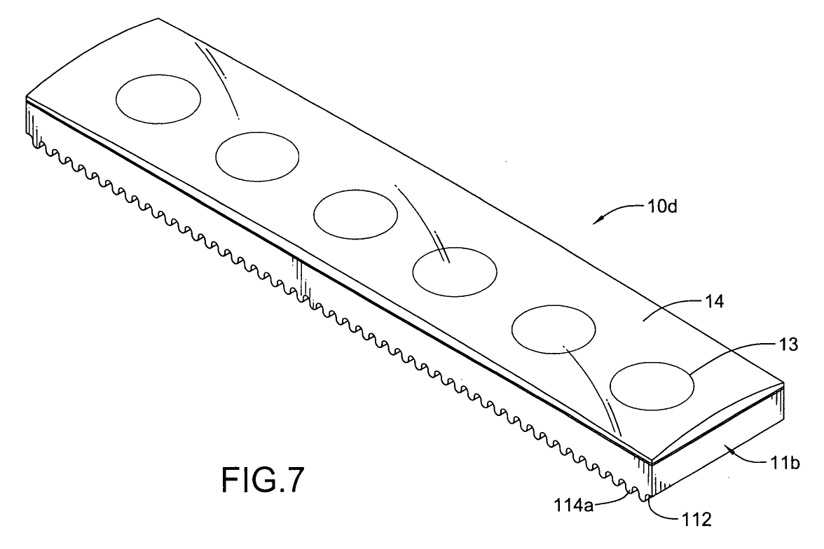

With reference to FIG. 7, a fifth embodiment of an LED light source model (10d) in accordance with the present invention is similar to the fourth embodiment and a plurality of fins (114a) on the substrate (11b) are formed as wave shapes and are also arranged parallel to each other on the bottom face (112) of the substrate (11b).

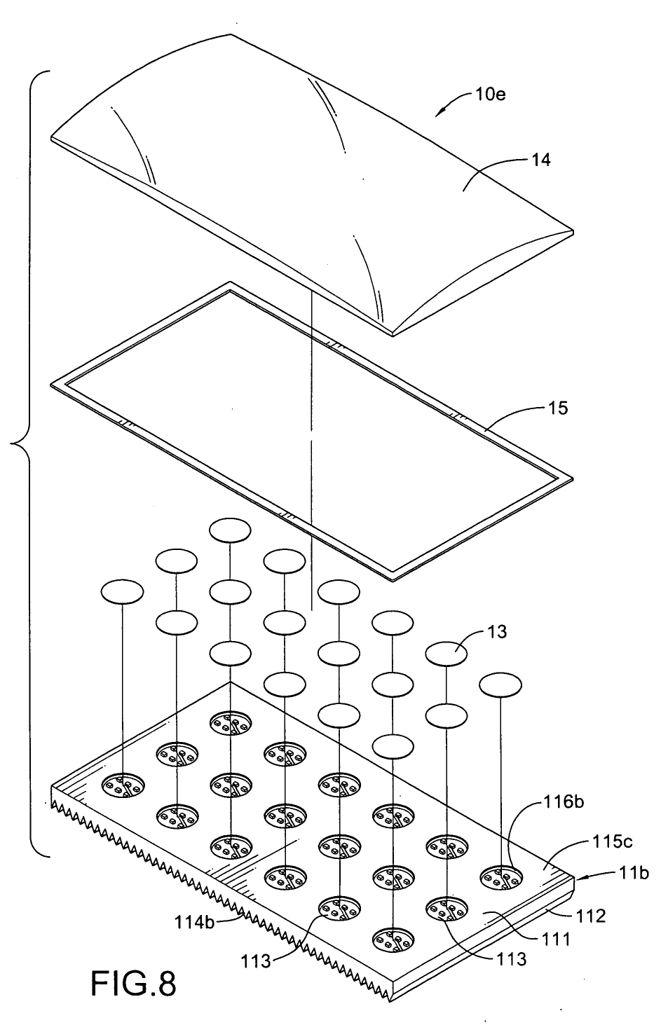

With reference to FIG. 8, a sixth embodiment of an LED source model (10f) in accordance with the present invention is similar to the fourth embodiment and has more bare LED chips (12), chip mounting areas (113), preformed phosphor laminas (13) and inner openings (116b) defined in the frame (115c). The chip mounting areas (113) are arranged in a matrix. Further, a plurality of fins (114b) of the substrate (11c) are formed as saw tooth shapes and are also arranged parallel on the bottom face (112) of the substrate (l 1c). In addition, the plurality of fins also can be formed as a grid.

Each embodiment of the present invention uses the preformed phosphor laminas (13) upon the bare LED chips (12) and each preformed phosphor lamina (13) has two opposite flat faces, so the light intensity from all of the bare LED chips (12) is even. In addition, a wavelength of light from the bare LED chips (12) is adjusted by the preformed phosphor lamina (13) when the light passes through the preformed phosphor lamina (13). Therefore, the bare LED chips (12) with different wavelengths can be used.

Further, since the substrate (11) is flat and has high thermal conductivity, heat from the bare LED chips (12) when operating will be conducted to the bottom face (121) and the LED light source model is suitable for a planar lamp or illumination device. The fins (14) or recesses are formed or defined on the bottom whereby the heat can be quickly dissipated to the ambient air. In addition, the optical light collecting elements (14) are mounted on the frame (115) such that the light from each preformed phosphor lamina (13) can be effectively collected. Therefore, the light intensity of the LED light source model is increased. Since the substrate (11) is a chip carrier and also a heat sink, the structure of the LED light source is simple.

Even though numerous characteristics and advantages of the present invention have been set forth in the foregoing description, together with details of the structure and function of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. An LED light source model, comprising:
a substrate having a top face, a bottom face and at least one chip mounting area;
a frame having at least one inner opening and mounted on the top face of the substrate, wherein the at least one inner opening corresponds respectively to the at least one chip mounting area;
at least one bare LED chip mounted in each one of the at least one chip mounting area;
at least one preformed phosphor lamina mounted respectively in the at least one inner opening to attach to the at least one bare LED chip; and
an optical light collecting element mounted on the frame through an adhesive layer on the frame.

2. The LED light source model as claimed in claim 1, further comprising a plurality of fins formed on the bottom face of the substrate.

3. The LED light source model as claimed in claim 1, further comprising a plurality of recesses defined on the bottom face of the substrate.

4. The LED light source model as claimed in claim 1, wherein the optical light collecting element is an optical lens.

5. The LED light source model as claimed in claim 1, further comprising a glue layer formed in at least one chip mounting area to fix the at least one preformed phosphor lamina in the at least one inner opening.

6. The LED light source model as claimed in claim 2, wherein each fin is formed as a straight shape.

7. The LED light source model as claimed in claim 2, wherein each fin is formed as a wave shape.

8. The LED light source model as claimed in claim 2, wherein each fin is formed as a saw tooth shape.

9. The LED light source model as claimed in claim 1, wherein the substrate is made of metallic material.

10. The LED light source model as claimed in claim 1, wherein the substrate is made of nonmetallic material with high thermal conductivity.

11. The LED light source model as claimed in claim 1, wherein the frame and the substrate are formed integrally.

12. The LED light source model as claimed in claim 11, further comprising a plurality of fins formed on the bottom face of the substrate.

13. The LED light source model as claimed in claim 11, further comprising a plurality of recesses defined on the bottom face of the substrate.

14. The LED light source model as claimed in claim 11, wherein the optical light collecting element is an optical lens.

15. The LED light source model as claimed in claim 11, further comprising a glue layer formed in at least one chip mounting area to fix the at least one preformed phosphor lamina in the corresponding at least one inner opening.

16. The LED light source model as claimed in claim 12, wherein each fin is formed as a straight shape.

17. The LED light source model as claimed in claim 12, wherein each fin is formed as a wave shape.

18. The LED light source model as claimed in claim 12, wherein each fin is formed as a saw tooth shape.

19. The LED light source model as claimed in claim 11, wherein the substrate is made of metallic material.

20. The LED light source model as claimed in claim 11, wherein the substrate is made of nonmetallic material with high thermal conductivity.
